(19) United States
(12) Patent Application Publication
(10) Pub. No.: US 2026/0047093 A1
(43) Pub. Date: Feb. 12, 2026

(54) SEMICONDUCTOR DEVICES AND METHODS OF FORMING SEMICONDUCTOR DEVICES USING LATERAL SOLID-PHASE EPITAXY

(71) Applicant: GLOBALFOUNDRIES U.S. Inc., Malta, NY (US)

(72) Inventors: Halid MULAOSMANOVIC, Dresden (DE); Judson Robert HOLT, Ballston Lake, NY (US); Peter BAARS, Dresden (DE)

(21) Appl. No.: 18/795,994

(22) Filed: Aug. 6, 2024

(51) Int. Cl. H10B 43/27

(52) U.S. Cl. CPC H10B 43/27

(57) ABSTRACT

A semiconductor device includes a semiconductor substrate, a channel disposed over the semiconductor substrate and extending in a specific direction, a drain disposed at a first end of the channel, a source disposed at a second end of the channel, and a gate disposed over the channel and configured to control a current through the channel. The gate, or the channel, or both include a semiconductor material that is monocrystalline.

### BACKGROUND

The present disclosure relates to a semiconductor device and a method of forming the semiconductor device using lateral solid-phase epitaxy. For example, such a semiconductor device may include a flash memory device, a vertical transistor, and a horizontal transistor.

A conventional semiconductor device may include memory cells having polycrystalline control gates and channel regions, which may deteriorate the performance of the semiconductor device. For example, diffusion of dopant in the polycrystalline control gates along grain boundaries may make the doping distribution within the gates non-uniform, and Fermi-level pinning at the grain boundaries may lead to threshold voltage (VT) fluctuations. Grain boundaries in the polycrystalline channel region may reduce turn-on current (ION) and increase random trapping and detrapping of charge carriers, thereby reducing operation performance of the conventional semiconductor device.

### SUMMARY

Embodiments of the present application relate to a semiconductor device, and a method of forming the semiconductor device using lateral solid-phase epitaxy. For example, such a semiconductor device may include a flash memory device, a vertical transistor, and a horizontal transistor.

In an embodiment, a semiconductor device includes a semiconductor substrate, a channel disposed over the semiconductor substrate and extending in a specific direction, a drain disposed at a first end of the channel, a source disposed at a second end of the channel, and a gate disposed over a surface of the channel and configured to control a current through the channel. The channel and the gate each include a semiconductor material that is substantially monocrystalline.

In an embodiment, a semiconductor device includes a semiconductor substrate, a first semiconductor layer disposed over the semiconductor substrate and extending in a first direction, a second semiconductor layer disposed over the first semiconductor layer and extending in the first direction, a dielectric layer disposed between the first semiconductor layer and the second semiconductor layer, a channel contacting the substrate and extending in a second direction to pass through the first semiconductor layer, the second semiconductor layer, and the dielectric layer, and a charge trap layer wrapping around the channel. The first semiconductor layer, the second semiconductor layer, and the channel each include a semiconductor material that is substantially monocrystalline.

In an embodiment, a method of forming a semiconductor device includes forming a first semiconductor layer over the semiconductor substrate, the first semiconductor layer extending in a first direction, forming a second semiconductor layer over the first semiconductor layer, the second semiconductor layer extending in the first direction, forming a dielectric layer between the first semiconductor layer and the second semiconductor layer, forming a channel that contacts the substrate and extends in a second direction to pass through the first semiconductor layer, the second semiconductor layer, and the dielectric layer, and forming a charge trap layer that wraps around the channel. The first semiconductor layer, the second semiconductor layer, and the channel each include a semiconductor material that is substantially monocrystalline.

### BRIEF DESCRIPTION OF THE DRAWINGS

FIG. 1 illustrates a simplified cross-sectional view of a semiconductor device according to an embodiment.

FIGS. 2A, 2B, 2C, 2D, 2E, 2F, 2G, and 2H illustrate a method of fabricating the semiconductor device of FIG. 1 according to an embodiment.

FIG. 3 illustrates a simplified cross-sectional view of a semiconductor device according to an embodiment of the present disclosure.

FIG. 4 illustrates a simplified cross-sectional view of a semiconductor device according to an embodiment.

FIG. 5 illustrates a simplified cross-sectional view of a semiconductor device according to an embodiment.

### DETAILED DESCRIPTION

A detailed description of embodiments is provided below along with accompanying figures. The scope of this disclosure is limited by the claims and encompasses numerous alternatives, modifications and equivalents. Although steps of various processes are presented in a given order, embodiments are not necessarily limited to being performed in the listed order. In some embodiments, certain operations may be performed simultaneously, in an order other than the described order, or not performed at all.

Numerous specific details are set forth in the following description. These details are provided to promote a thorough understanding of the scope of this disclosure by way of specific examples, and embodiments may be practiced according to the claims without some of these specific details. Accordingly, the specific embodiments of this disclosure are illustrative, and are not intended to be exclusive or limiting. For the purpose of clarity, technical material that is known in the technical fields related to this disclosure has not been described in detail so that the disclosure is not unnecessarily obscured.

In the present disclosure, a semiconductor material may be designated monocrystalline when crystal lattice structure thereof has a long-range order of arrangement and lacks grain boundaries associated with a polycrystalline semiconductor material. A semiconductor material may be considered to be monocrystalline (or a single-crystal semiconductor material) even if crystallographic defects, such as dislocations, are incorporated as imperfections.

As used in the present disclosure, including in the claims, “or” as used in a list of items (e.g., a list of items prefaced by a phrase such as “at least one of,” “one or more of,” or “one or both of”) indicates an inclusive list such that, for example, a list of at least one of A, B, or C indicates A or B or C or AB or AC or BC or ABC (i.e., A and B and C), and a list of one or both of A and B indicates A or B or AB.

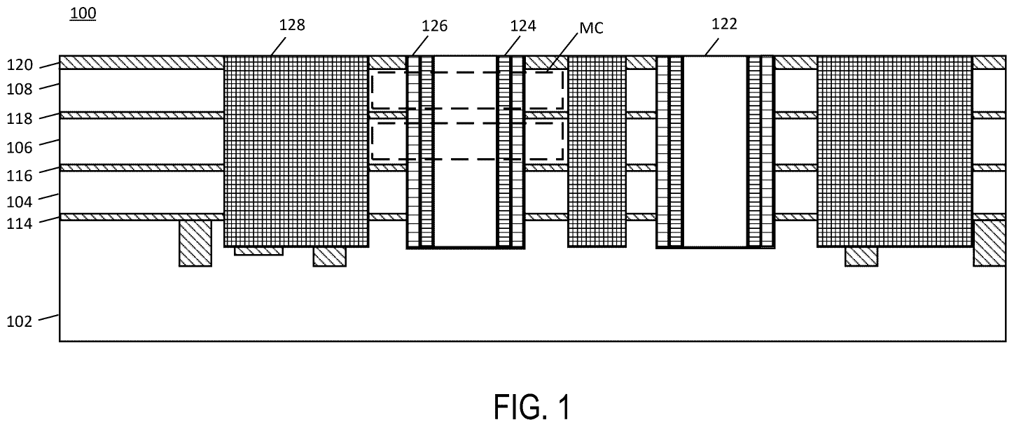

FIG. 1 illustrates a simplified cross-sectional view of a semiconductor device 100 according to an embodiment. In an embodiment, the semiconductor device 100 is a 3D NAND flash. For example, the semiconductor device 100 may have Bit-Cost Scalable (BiCS) architecture.

Referring to FIG. 1, the semiconductor device 100 includes a substrate 102. In an embodiment, the substrate 102 includes a semiconductor material that is monocrystalline (or a single-crystal semiconductor material). For example, the substrate 102 may include at least one of monocrystalline silicon, monocrystalline silicon-germanium, or monocrystalline germanium.

The semiconductor device 100 in FIG. 1 further includes first, second, and third semiconductor layers 104, 106, and 108, and first, second, third, and fourth dielectric layers 114, 116, 118, and 120 that are disposed over the substrate 102. For example, the first, second, and third semiconductor layers 104, 106, and 108 and first, second, third, and fourth dielectric layers 114, 116, 118, and 120 are stacked alternately in a specific direction (e.g., a vertical direction in FIG. 1) over a surface (e.g., an upper surface) of the substrate 102.

The semiconductor layers 104, 106, and 108 in FIG. 1 each includes a semiconductor material. In an embodiment, each of the semiconductor layers 104, 106, and 108 has the same semiconductor material as the substrate 102. Specifically, the semiconductor layers 104, 106, and 108 may include the same semiconductor material that is monocrystalline. In addition, each of the semiconductor layers 104, 106, and 108 may have the same crystal orientation as that of the substrate 102.

The semiconductor device 100 in FIG. 1 includes a plurality of memory strings, each of which includes a plurality of memory cells MC connected in series. The memory cell MC in FIG. 1 includes a portion of a channel 122, a portion of a tunnel oxide layer 124 adjacent to the portion of the channel 122, and a portion of a charge trap layer 126 adjacent to the portion of the tunnel oxide layer 124 as well as a portion of the semiconductor layer 106 or 108 adjacent to the portion of the charge trap layer 126. The portion of the semiconductor layers 106 or 108 in the memory cell MC may function as a control terminal (e.g., a gate) of the memory cell MC, such that the control terminal may be disposed over a sidewall of the channel 122. The channel 122 in FIG. 1 includes a single-crystal semiconductor material that is the same as the substrate 102, and has the same crystal orientation as that of the substrate 102. The channel 122 in FIG. 1 extends in a direction substantially orthogonal to an upper surface of the substrate 102.

The first semiconductor layer 104 includes portions adjacent to the charge trap material 126, such that the portions of the first semiconductor layer 104 and corresponding portions of the charge trap material 126, the tunnel oxide layer 124, and the channel 122 together function as selectors (e.g., source line selectors) of the memory strings. Although the selectors according to the embodiment of FIG. 1 include corresponding portions of the charge trap material 126, embodiments of the present disclosure are not limited thereto. For example, selectors at a source side and a drain side may be formed to omit corresponding portions of the charge trap material 126. Although the semiconductor device 100 in FIG. 1 includes three semiconductor layers 104, 106, and 108, embodiments of the present disclosure are not limited thereto. For example, the number of semiconductor layers stacked over the substrate 102 may vary according to embodiments.

The semiconductor device 100 in FIG. 1 further includes interlayer dielectric materials 128 to fill a space between memory cells MC. In an embodiment, the interlayer dielectric materials 128 may include the same dielectric material (e.g., silicon dioxide) as the first, second, third, and fourth dielectric layers 114, 116, 118, and 120. However, embodiments of the present disclosure are not limited thereto. For example, the interlayer dielectric materials 128 may include a material having better properties to effectively fill a space with a relatively high aspect ratio, compared to a material of the first to fourth dielectric layers 114 to 120.

Although not shown in FIG. 1, the semiconductor device 100 may further include selectors (e.g., bit line selectors) and conductive lines (e.g., bit lines) over the structure of FIG. 1. The semiconductor substrate 102 in FIG. 1 may serve as a source plane, such that the plurality of memory strings are connected between the source plane and the bit lines. The semiconductor device 100 in FIG. 1 may further include a drain that is disposed at a first end of the channel 122 and connected to the bit line and a source that is disposed at a second end of the channel 122 and in an upper portion of the substrate 102. In some embodiments, the semiconductor device 100 may include an additional layer (e.g., an oxide layer) between the charge trap layer 126 and portions of the first, second, and third semiconductor layers 104, 106, and 108 that function as control gates of the memory cells MC.

A semiconductor device according to an embodiment of the present disclosure includes the memory cells MC each having a control gate, or a channel region, or both that are monocrystalline. For example, the semiconductor device 100 in FIG. 1 may include control gates of the memory cells MC and the channel 122 that are monocrystalline, and thus address various issues (e.g., non-uniform doping distribution within polycrystalline control gates, increased threshold voltage fluctuations, reduced turn-on current, increased random trapping/detrapping of charge carriers, etc.) associated with the polycrystalline control gates and channels of a conventional semiconductor device. As a result, a semiconductor device according to an embodiment of the present disclosure may exhibit improved operation performance (e.g., program/erase efficiency in 3D NAND flash) compared to the conventional semiconductor device.

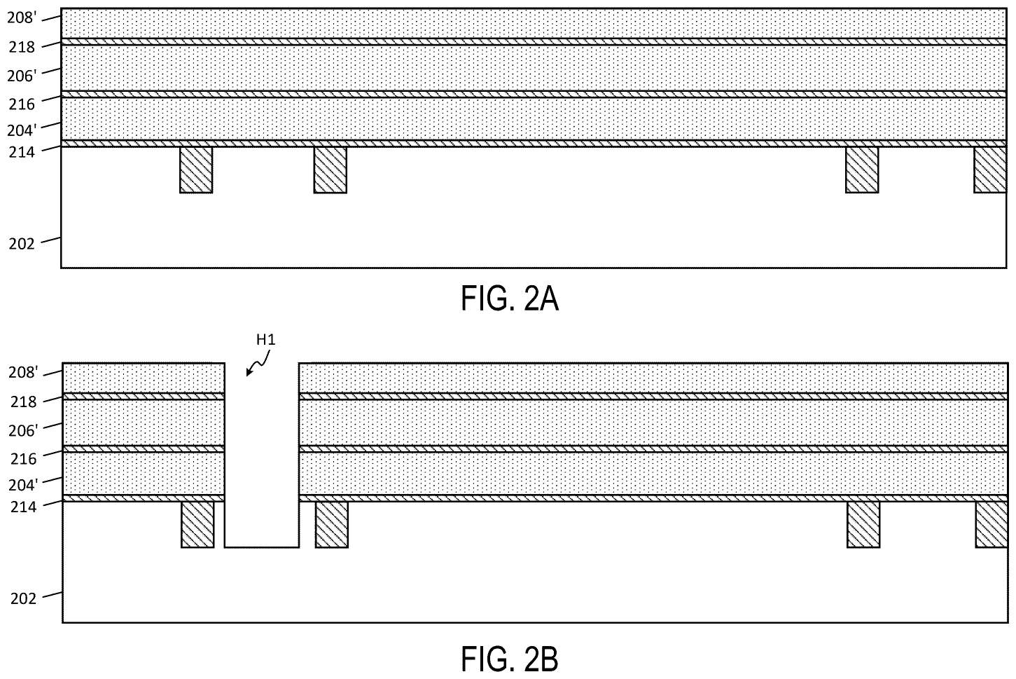

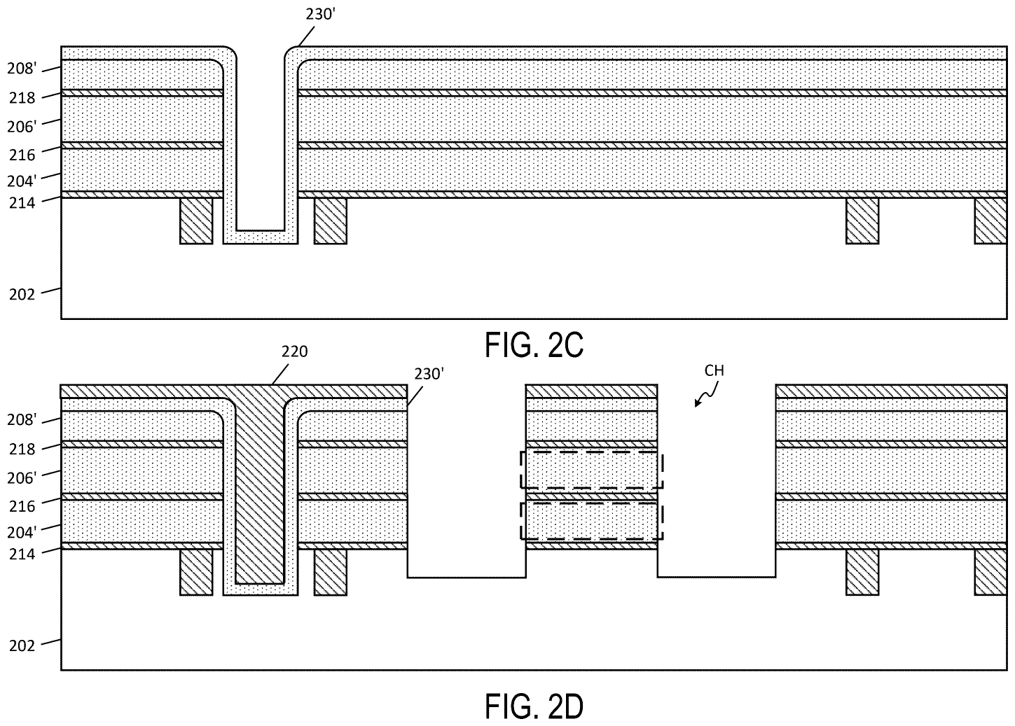

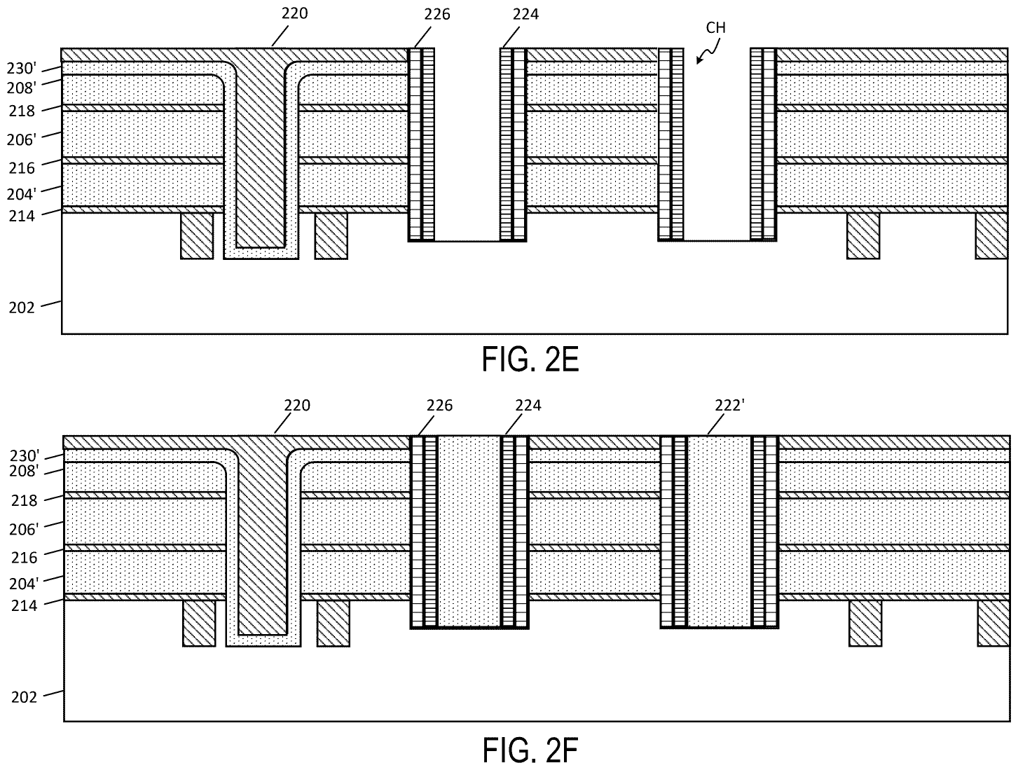

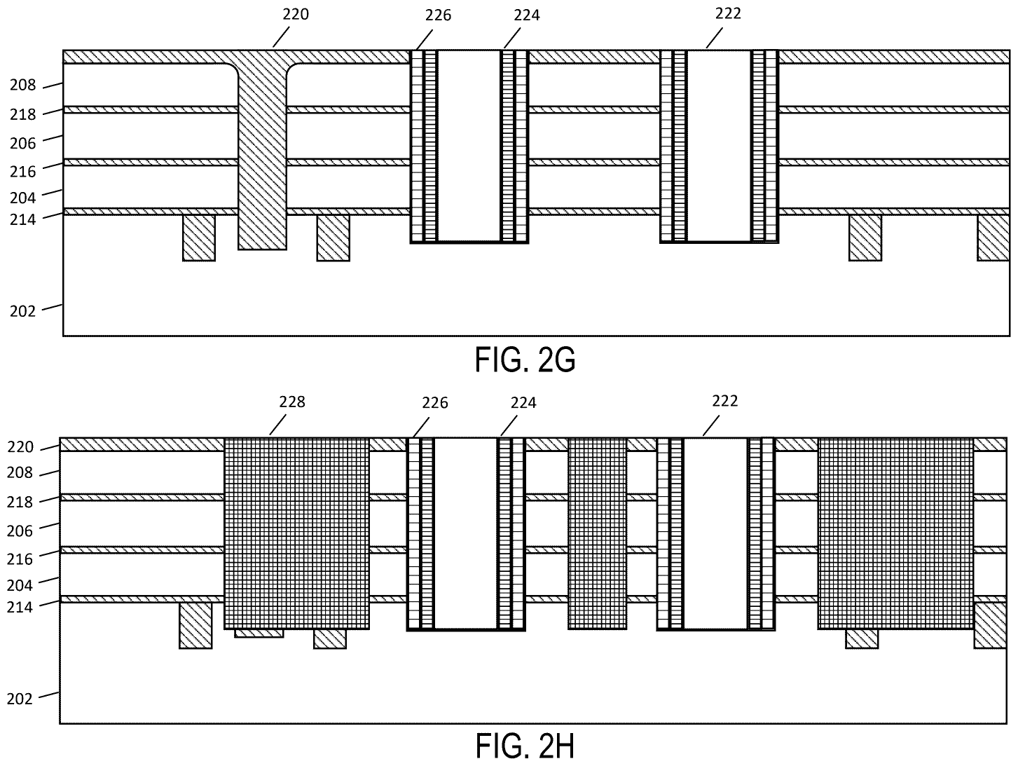

FIGS. 2A, 2B, 2C, 2D, 2E, 2F, 2G, and 2H illustrate a method of fabricating the semiconductor device 100 in FIG. 1 according to an embodiment. Specifically, FIGS. 2A, 2B, 2C, 2D, 2E, 2F, 2G, and 2H are simplified cross-sectional views corresponding to the cross-sectional view of FIG. 1.

Referring to FIG. 2A, the method includes providing a substrate 202 and forming first, second, and third initial semiconductor layers 204′, 206′, and 208′ and first, second, and third dielectric layers 214, 216, and 218 over the substrate 202. In an embodiment, the first, second, and third dielectric layers 214, 216, and 218 and the first, second, and third initial semiconductor layers 204′, 206′, and 208′ are formed alternately using blanket deposition processes. In an embodiment, the first, second, and third initial semiconductor layers 204′, 206′, and 208′ each include a semiconductor material that is the same as that of the substrate 202 while having an atomic structure different from that of the substrate 202. For example, the substrate 202 includes a semiconductor material that is monocrystalline (e.g., monocrystalline silicon, monocrystalline silicon-germanium, or monocrystalline germanium), whereas the first, second, and third initial semiconductor layers 204′, 206′, and 208′ each include the same semiconductor material that is amorphous (e.g., amorphous silicon, amorphous silicon-germanium, or amorphous germanium). The first, second, and third dielectric layers 214, 216, and 218 each may include an oxide (e.g., silicon dioxide).

In an embodiment, the first, second, and third initial semiconductor layers 204′, 206′, and 208′ are in-situ doped during deposition, or doped during post-deposition by ion implantation. In an embodiment, the first initial semiconductor layer 204′, the second initial semiconductor layer 206′, and/or the third initial semiconductor layers 208′ may be doped to have the same conductivity type. In an embodiment, the first initial semiconductor layer 204′, the second initial semiconductor layer 206′, and/or the third initial semiconductor layers 208′ may be doped to have different conductivity types.

Referring to FIG. 2B, the method includes forming one or more openings H1 that expose the substrate 202. In an embodiment, a plurality of openings H1 may be formed in a predetermined pattern to extend to an upper surface of the substrate 202.

Referring to FIG. 2C, the method includes forming an initial liner 230′ over the structure shown in FIG. 2B. For example, the initial liner 230′ may include a semiconductor material that is the same as that of the substrate 202. In an embodiment, the initial liner 230′ may be formed using a deposition process to make a thickness of the initial liner 230′ relatively thin and ensure sufficient contact of the liner 230′ with the substrate 202 and the initial semiconductor layers 204′, 206′, and 208′. For example, the initial semiconductor liner 230′ may be formed using low-pressure chemical vapor deposition (LPCVD) to ensure deposition of a uniform thin liner (e.g., not greater than 100 nm) with good contact of the liner 230′ with the substrate 202 and the initial semiconductor layers 204′, 206′, and 208′. In an embodiment, the initial liner 230′ may be formed in an amorphous phase using a deposition process at a temperature sufficiently low to substantially prevent crystallization of the initial liner 230′ and the initial semiconductor layers 294′, 206′, and 208′. For example, the initial liner 230′ may be formed at a temperature lower than about 600° C.

Referring to FIG. 2D, the method includes forming a fourth dielectric layer 220 over the structure shown in FIG. 2C, and forming a plurality of recesses CH that expose the substrate 202. In an embodiment, the plurality of recesses CH may be formed in a predetermined pattern to extend to an upper surface of the substrate 202 using an anisotropic etching process (e.g., reactive ion etching (RIE) process). For example, the plurality of recesses CH may be arranged to correspond to regions where a plurality of memory strings are to be formed, respectively, as will be described below in more detail with reference to FIGS. 2E, 2F, and 2G.

Although FIG. 2D shows some portions (indicated by dashed line rectangles in FIG. 2D) of the initial semiconductor layers 204′ and 206′ that do not appear to be in contact with the initial liner 230′, these portions of the initial semiconductor layers 204′ and 206′ are in contact with the initial liner 230′ disposed over other openings H1 formed in the process of FIG. 2B. Specifically, the initial liner 230′ may extend in a direction orthogonal to the plane defining the cross-sectional view of FIG. 2D and be deposited over a plurality of openings H1 (not shown in FIG. 2B) to be in contact with the portions (indicated by the dashed line rectangles) of the initial semiconductor layers 206′ and 204′. As a result, the initial liner 230′ may connect the substrate 202 to the portions (indicated by the dashed line rectangles) of the initial semiconductor layers 206′ and 204′ in regions outside the plane.

Referring to FIG. 2E, the method includes forming a charge trap layer 226 over a sidewall of each of the recesses CH. In an embodiment, the charge trap layer 226 may be formed by depositing a charge trap material over the structure shown in FIG. 2D, and performing anisotropic etch to remain portions of the deposited material over the sidewalls of the recesses CH. For example, the charge trap material layer 226 may include silicon nitride.

The method according to the embodiment of FIG. 2E may further include forming a tunnel oxide layer 224 over the charge trap layer 226. In an embodiment, the tunnel oxide layer 224 may be formed by depositing a tunnel oxide material over the fourth dielectric layer 220 and the charge trap layer 226, and performing an anisotropic etch process to remain portions of the deposited material over the sidewalls of the charge trap layer 226.

Although not shown in FIG. 2E, the method may further include forming one or more additional layers between the charge trap layer 226 and a sidewall of the recess CH in FIG. 2D. In an embodiment, before forming the charge trap layer 226, an oxide layer (not shown) may be formed by depositing an oxide material over the structure shown in FIG. 2D, and performing anisotropic etch to remain portions of the deposited material over the sidewalls of the recesses CH.

Referring to FIG. 2F, the method includes forming initial channels 222′ in the respective recesses CH. In an embodiment, the initial channels 222′ are formed by depositing a semiconductor material over the structure shown in FIG. 2E to fill the recesses CH, and performing a planarization process (e.g., CMP process) to remove residual material over an upper surface of the fourth dielectric layer 220. For example, the initial channel 222′ may be formed in an amorphous phase.

Referring to FIG. 2G, the method includes converting the initial liner 230′ and the initial semiconductor layers 204′, 206′, and 208′ into first, second, and third semiconductor layers 204, 206, and 208. In an embodiment, a lateral solid-phase epitaxy process is used to covert the initial liner 230′ and the initial the initial semiconductor layers 204′, 206′, and 208′ in an amorphous phase into first, second, and third semiconductor layers 204, 206, and 208 in a monocrystalline phase (or a single-crystal phase). For example, the lateral solid-phase epitaxy process may include a thermal anneal at a substrate temperature of about 600° C. for a given anneal time and in an inert gas environment. Some details of the lateral solid-phase epitaxy process and various structures using the process can be found in pending U.S. patent application Ser. No. 18/420,998, entitled “STRUCTURES INCLUDING A SEMICONDUCTOR LAYER FORMED BY LATERAL EPITAXIAL GROWTH” and filed on Jan. 24, 2024, the entire contents of which are incorporated herein by reference.

Referring to FIGS. 2F and 2G together, portions of the substrate 202 in direct contact with the initial liner 230′ operate as single-crystal seeds during the lateral solid-phase epitaxy process, and thus the initial liner 230′ in an amorphous phase is converted into a monocrystalline phase. When the initial liner 230′ is converted into a monocrystalline phase, the initial semiconductor layers 204′, 206′, and 208′ in an amorphous phase are converted into the semiconductor layers 204, 206, and 208 in a monocrystalline phase. As a result, each of the semiconductor layers 204, 206, and 208 may include a semiconductor material that is monocrystalline (or a single-crystal semiconductor material), and have the same crystal orientation as that of the substrate 202.

The monocrystalline semiconductor material contained in each of the semiconductor layers 204, 206, and 208 may extend laterally over the respective underlying dielectric layers 214, 216, and 218. The lateral solid-phase epitaxy process may exhibit long-range crystallization in which the lateral extent of the monocrystalline semiconductor material of the semiconductor layers 204, 206, and 208 exceeds a conventional limit for lateral growth over a dielectric layer.

The method in FIG. 2G further includes converting the initial channels 222′ into the channels 222. In an embodiment, portions of the substrate 202 in contact with the initial channels 222′ operate as single-crystal seeds during a thermal anneal, and thus the initial channels 222′ in an amorphous phase is converted into the channels 222 in a monocrystalline phase. As a result, the channels 222 may include a semiconductor material that is monocrystalline (or a single-crystal semiconductor material), and have the same crystal orientation as that of the substrate 202.

Referring to FIG. 2H, the method includes forming interlayer dielectric materials 228. For example, the interlayer dielectric materials 228 may be formed by forming trenches, filling the trenches with a dielectric material, and performing a planarization process. In an embodiment, the interlayer dielectric materials 228 may include the same dielectric material (e.g., silicon dioxide) as the first, second, third, and fourth dielectric layers 214, 216, 218, and 220. In an embodiment, the interlayer dielectric materials 228 may include a dielectric material different from that of the first, second, third, and fourth dielectric layers 214, 216, 218, and 220 to effectively fill the trenches with a relatively high aspect ratio.

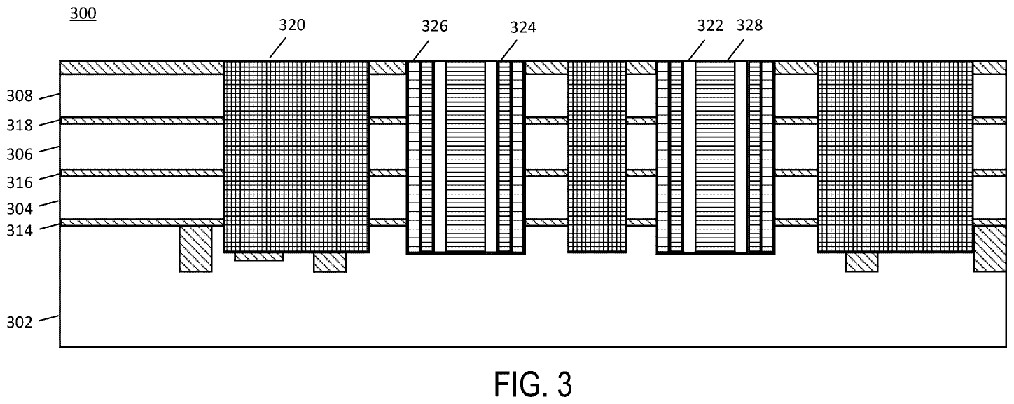

FIG. 3 illustrates a simplified cross-sectional view of a semiconductor device 300 according to an embodiment of the present disclosure. The semiconductor device 300 in FIG. 3 includes similar elements to those of the semiconductor device 100 of FIG. 1, and thus detailed descriptions on these elements may be omitted in the following disclosure for the interest of brevity.

The semiconductor device 300 of FIG. 3 differs from the semiconductor device 100 of FIG. 1 in that the semiconductor device 300 includes a plurality of memory strings each having a tube-shaped channel (e.g., a macaroni-shaped channel) 322, rather than a cylinder-shaped channel 122 of the semiconductor device 100, and that a dielectric core 328 is disposed within the macaroni-shaped channel 322. Since the semiconductor device 300 have the channel 322 with a relatively thin thickness to make threshold voltage less sensitive to trap density fluctuation, the semiconductor device 300 of FIG. 3 may exhibit improved operation reliability compared to the semiconductor device 100 of FIG. 1.

A method of fabricating the semiconductor device 300 in FIG. 3 according to an embodiment includes forming an initial liner (e.g., an initial semiconductor liner) over the structure shown in FIG. 2E and performing an anisotropic etching process to form initial macaroni-shaped channels. Subsequently, a dielectric material may be formed to fill a space inside of each of the initial macaroni-shaped channels and performing a planarization process to form the dielectric cores 328.

The method further includes converting the initial macaroni-shaped channels into the macaroni-shaped channels 322. In an embodiment, portions of the substrate 302 in contact with the initial macaroni-shaped channels operate as single-crystal seeds during a thermal anneal, and thus the initial macaroni-shaped channels in an amorphous phase are converted into the macaroni-shaped channels 322 in a monocrystalline phase.

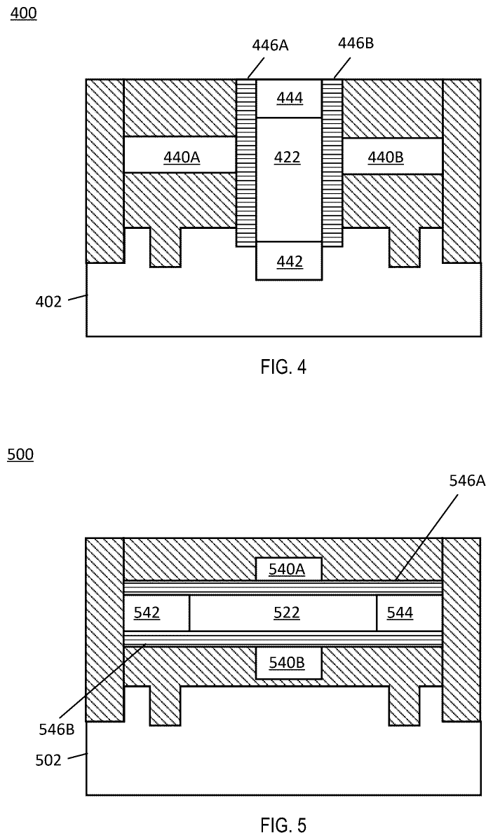

FIG. 4 illustrates a simplified cross-sectional view of a semiconductor device 400 according to an embodiment. In an embodiment, the semiconductor device 400 is a vertical transistor. Repetitive descriptions on some elements of the semiconductor device 400 may be omitted in the following disclosure for the interest of brevity.

Referring to FIG. 4, the semiconductor device 400 includes a substrate 402, a first terminal (e.g., a drain) 444, a second terminal (e.g., a source) 442, a channel 422, a first control terminal (e.g., a first gate) 440A, a second control terminal (e.g., a second gate) 440B, a first oxide (e.g., a first gate oxide) 446A, and a second oxide (e.g., a second gate oxide) 446B.

Each of the first and second gates 440A and 440B in FIG. 4 may include the same semiconductor material with substantially the same atomic structure as the substrate 402. For example, each of the first and second gates 440A and 440B includes a semiconductor material that is monocrystalline and has the same crystal orientation as that of the substrate 402. In an embodiment, the first gate 440A may be disposed over a first sidewall of the channel 422 and the second gate 440B may be disposed over a second sidewall of the channel 422 opposite to the first sidewall. In such an embodiment, the first gate oxide 446A may be disposed between the first gate 440A and the first sidewall of the channel 422, and the second gate oxide 446B may be disposed between the second gate 440B and the second sidewall of the channel 422.

The first and second gates 440A and 440B in FIG. 4 may be formed by converting an initial liner (not shown) and initial gates (not shown) connected to the initial liner into the first and second gates 440A and 440B. In an embodiment, a thermal anneal (e.g., a lateral solid-phase epitaxy process) may be used to convert the initial liner and the initial gates in an amorphous phase into the first and second gates 440A and 440B in a monocrystalline phase, similarly to the above-described process with reference to FIG. 2G.

The channel 422 in FIG. 4 may include the same semiconductor material with substantially the same atomic structure as the substrate 402. For example, the channel 422 includes a semiconductor material that is monocrystalline and has the same crystal orientation as that of the substrate 402.

The channel 422 in FIG. 4 may be formed by converting an initial channel (not shown) into the channel 422. In an embodiment, a portion of the substrate 402 in contact with the channel 422 operates as a single-crystal seed during a thermal anneal, and thus the initial channel in an amorphous phase is converted into the channel 422 in a monocrystalline phase.

Although the semiconductor device 400 according to the embodiment shown in FIG. 4 includes a pair of gates 440A and 440B and a pair of oxide gates 446A and 446B, embodiments of the present disclosure are not limited thereto. For example, the semiconductor device 400 may include a single integrated gate and a single integrated oxide gate that wrap around a cylinder-shaped channel 422.

FIG. 5 illustrates a simplified cross-sectional view of a semiconductor device 500 according to an embodiment. In an embodiment, the semiconductor device 500 is a horizontal transistor. Repetitive descriptions on some elements of the semiconductor device 500 may be omitted in the following disclosure for the interest of brevity.

Referring to FIG. 5, the semiconductor device 500 includes a substrate 502, a first terminal (e.g., a source) 542, a second terminal (e.g., a drain) 544, a channel 522, a first control terminal (e.g., a first gate) 540A, a second control terminal (e.g., a second gate) 540B, a first oxide (e.g., a first gate oxide) 546A, and a second oxide (e.g., a second gate oxide) 546B.

Each of the first and second gates 540A and 540B in FIG. 5 may include the same semiconductor material with substantially the same atomic structure as the substrate 502. For example, each of the first and second gates 540A and 540B includes a semiconductor material that is monocrystalline and has the same crystal orientation as that of the substrate 502. In an embodiment, the first gate 540A may be disposed over an upper surface of the channel 522 and the second gate 540B may be disposed over a lower surface of the channel 522. In such an embodiment, the first gate oxide 546A may be disposed between the first gate 540A and the upper surface of the channel 522, and the second gate oxide 546B may be disposed between the second gate 540B and the lower surface of the channel 522.

The channel 522 in FIG. 5 may include the same semiconductor material with substantially the same atomic structure as the substrate 502. For example, the channel 522 includes a semiconductor material that is monocrystalline and has the same crystal orientation as that of the substrate 502.

The first and second gates 540A and 540B and the channel 522 in FIG. 5 may be formed by converting an initial liner (not shown), initial gates (not shown), and initial channel (not shown) into the first and second gates 540A and 540B and the channel 522. For example, the initial liner may be formed to connect the substrate 502 to the initial gates and the initial channel. In an embodiment, a thermal anneal (e.g., a lateral solid-phase epitaxy process) may be used to convert the initial liner, the initial gates, and the initial channel in an amorphous phase into the first and second gates 540A and 540B and the channel 522 in a monocrystalline phase, similarly to the above-described process with reference to FIG. 2G. Subsequently, some portions of the converted liner may be removed to disconnect the remaining portions of the liner from the gates 540A and 540B and the channel 522 by performing an etching process.

A semiconductor device according to an embodiment of the present disclosure may include gates and channels that are monocrystalline. As a result, such a semiconductor device according to an embodiment of the present disclosure may exhibit improved operation performance compared to a conventional semiconductor device including polycrystalline gates and/or channels. Such gates, or channels, or both of a semiconductor device according to an embodiment of the present disclosure may be formed using a lateral solid-phase epitaxy process that exhibits long-range crystallization to exceed a conventional limit for lateral growth over a dielectric layer.

Aspects of the present disclosure have been described in conjunction with the specific embodiments thereof that are proposed as examples. Numerous alternatives, modifications, and variations to the embodiments as set forth herein may be made without departing from the scope of the claims set forth below. Accordingly, embodiments as set forth herein are intended to be illustrative and not limiting.

1. A semiconductor device, comprising:
a semiconductor substrate;
a channel disposed over the semiconductor substrate and extending in a specific direction;
a drain disposed at a first end of the channel;
a source disposed at a second end of the channel; and
a gate disposed over the channel and configured to control a current through the channel,
wherein the gate, or the channel, or both include a semiconductor material that is monocrystalline.

2. The semiconductor device of claim 1, wherein the gate and the channel each include the same semiconductor material as that of the substrate.

3. The semiconductor device of claim 2, wherein the gate and the channel each have the same crystal orientation as that of the substrate.

4. The semiconductor device of claim 1, wherein the channel extends in the direction substantially orthogonal to an upper surface of the substrate, the gate is disposed over a sidewall of the channel, and the device further comprises a charge trap layer disposed between the channel and the gate.

5. The semiconductor device of claim 4, wherein the device further comprises a tunnel oxide layer disposed between the channel and the charge trap layer.

6. The semiconductor device of claim 5, wherein the channel is a tube-shaped channel, and the device further comprises a dielectric core disposed within the channel.

7. The semiconductor device of claim 1, wherein the channel extends in the direction substantially orthogonal to an upper surface of the substrate; and
a gate oxide disposed between the channel and the gate.

8. The semiconductor device of claim 7, wherein the gate is a first gate disposed over a first sidewall of the channel and the gate oxide is a first gate oxide disposed between the first gate and the channel, the device further comprising:
a second gate disposed over a second sidewall of the channel opposite to the first sidewall of the channel; and
a second gate oxide disposed between the second gate and the channel, and
wherein the second gate includes the semiconductor material that is monocrystalline.

9. The semiconductor device of claim 1, wherein the channel extends in the direction substantially parallel to an upper surface of the substrate, and the device further comprises a gate oxide disposed between the channel and the gate.

10. The semiconductor device of claim 9, wherein the gate is a first gate disposed over an upper surface of the channel and the gate oxide is a first gate oxide disposed between the first gate and the channel, the device further comprising:
a second gate disposed over a lower surface of the channel; and
a second gate oxide disposed between the second gate and the channel, and
wherein the second gate includes the semiconductor material that is monocrystalline.

11. A semiconductor device, comprising:
a semiconductor substrate;
a first semiconductor layer disposed over the semiconductor substrate and extending in a first direction;
a second semiconductor layer disposed over the first semiconductor layer and extending in the first direction;
a first dielectric layer disposed between the first semiconductor layer and the second semiconductor layer;
a channel disposed over the substrate and extending in a second direction to pass through the first semiconductor layer, the second semiconductor layer, and the dielectric layer; and
a charge trap layer wrapping around the channel,
wherein the first semiconductor layer, the second semiconductor layer, and the channel each include a semiconductor material that is monocrystalline.

12. The semiconductor device of claim 11, wherein the first semiconductor layer, the second semiconductor layer, and the channel each include the same semiconductor material as that of the substrate.

13. The semiconductor device of claim 12, wherein the first semiconductor layer, the second semiconductor layer, and the channel each have the same crystal orientation as that of the substrate.

14. The semiconductor device of claim 11, wherein the semiconductor device includes a first memory cell, the first memory cell including a first portion of the channel, a first portion of the charge trap layer adjacent to the first portion of the channel, and a portion of the second semiconductor layer adjacent to the first portion of the charge trap layer.

15. The semiconductor device of claim 14, further comprising a tunnel oxide layer disposed between the channel and the charge trap layer.

16. The semiconductor device of claim 15, wherein the channel is a tube-shaped channel, and the device further comprises a dielectric core disposed within the channel.

17. The semiconductor device of claim 14, further comprising:
a third semiconductor layer disposed over the second semiconductor material layer and extending in the first direction; and
a second dielectric layer disposed between the second semiconductor layer and the third semiconductor layer,
wherein the third semiconductor layer includes the semiconductor material that is monocrystalline, and
wherein the semiconductor device further includes a second memory cell, the second memory cell including a second portion of the channel, a second portion of the charge trap layer adjacent to the second portion of the channel, and a portion of the third semiconductor layer adjacent to the second portion of the charge trap layer.

18. A method of forming a semiconductor device, comprising:
forming a first semiconductor layer and a second semiconductor layer over the semiconductor substrate, each of the first semiconductor layer and the second semiconductor layer extending in a first direction;
forming a dielectric layer between the first semiconductor layer and the second semiconductor layer;
forming a channel that contacts the substrate and extends in a second direction to pass through the first semiconductor layer, the second semiconductor layer, and the dielectric layer; and
forming a charge trap layer that wraps around the channel,
wherein the first semiconductor layer, the second semiconductor layer, and the channel each include a semiconductor material that is monocrystalline.

19. The method of claim 18, wherein forming the first semiconductor layer and the second semiconductor layer comprises:
forming a first initial semiconductor layer over the semiconductor substrate;
forming a second initial semiconductor layer over the first initial semiconductor layer;
forming an initial liner that connects the substrate to the first initial semiconductor layer and the second initial semiconductor layer; and
converting, by performing a solid-phase epitaxy process, the initial liner, the first initial semiconductor layer, and the second initial semiconductor layer that are in an amorphous phase into the first semiconductor layer and the second semiconductor layer that are monocrystalline.

20. The method of claim 19, wherein forming the channel comprises:
forming an initial channel that contacts the substrate and extends in the second direction; and
converting the initial channel in an amorphous phase into the channel that is crystalline.
